(19) United States
(12) Patent Application Publication
(10) Pub. No.: US 2012/0135610 A1
(43) Pub. Date: May 31, 2012

(54) SYSTEM AND METHOD FOR PROCESSING SUBSTRATE

(75) Inventor: Toshiyuki IDE, Miyazaki (JP)

(73) Assignee: LAPIS SEMICONDUCTOR CO., LTD., Tokyo (JP)

(21) Appl. No.: 13/299,668

(22) Filed: Nov. 18, 2011

(30) Foreign Application Priority Data
Nov. 25, 2010 (JP) 2010-262217

(51) Int. Cl. H01L 21/31; B05C 11/00

(52) U.S. Cl. 438/778; 118/699; 257/E21.24

(57) ABSTRACT

A substrate processing system including a cleaning equipment; a resist coating equipment forming a resist layer on a surface of a substrate; an edge exposure equipment that exposes to light an edge portion of the resist layer formed on a peripheral edge of the substrate; a substrate transport mechanism; and a system controller. The system controller includes a waiting time monitor and a process controller. The waiting time monitor monitors a waiting time that is a time interval between the formation of the resist layer and start of the exposure of the edge portion of the resist layer. The process controller causes the substrate transport mechanism to transport the substrate into the cleaning equipment when the monitored waiting time exceeds a prescribed limit, removing the resist layer from the substrate. The process controller then causes the substrate transport mechanism to transport the substrate into the resist coating equipment.

### BACKGROUND OF THE INVENTION

1. Field of the Invention

The present invention relates to techniques for light exposure of a photosensitive resin material formed on a substrate such as a wafer, and more particularly, to techniques for light exposure of an unnecessary photosensitive resin material formed on the peripheral edge of the substrate.

2. Description of the Related Art

Photolithography in semiconductor fabrication processes is widely used to form a photoresist pattern on a wafer. In the photolithography, a main surface of the wafer is entirely coated with a photosensitive resin material to form a photosensitive layer, and the photosensitive layer is exposed to a pattern of light that passes a reticle (i.e., a plate that has designed patterns including circuit patterns formed on a base substrate), thus transferring patterns of the reticle onto the photosensitive layer. The photosensitive layer is then developed and washed using an appropriate chemical solution to become the photoresist pattern. This photoresist pattern can be used as an etching mask to etch a layer beneath the photoresist pattern. The problem with the photolithography process is that the photosensitive resin material on the peripheral edge of the wafer could be separated from the wafer, thus becoming unwanted particles that cause lower manufacturing yield. In order to avoid the problem, a conventional wafer edge exposure can be performed in which only the unwanted portion of the photosensitive layer on the peripheral edge of the wafer is exposed to light prior to the wafer exposure process using the reticle.

However, the conventional wafer edge exposure possibly induces a photochemical reaction in the exposed portion of the photosensitive layer. The photochemical reaction generates bubbles in the exposed portion of the photosensitive layer. The bubbles cause fragments (bubble fragments) of the photosensitive layer to fly off and attach to the unexposed portion of the photosensitive layer. The problem is that the bubble fragments attached to the unexposed portion would lead to defects (pattern defects) in the photoresist pattern that is formed in a subsequent photolithography process.

FIGS. 1A to 1D are cross-sectional views illustrating exemplary pattern defects caused by bubble phenomenon in a conventional wafer edge exposure process. As illustrated in FIG. 1A, an underlying layer 41 to be processed and a photosensitive resist layer 43 are formed on a substrate 40, and the edge portion of the photosensitive resist layer 43 on the peripheral edge of the substrate is exposed to light LB in the conventional wafer edge exposure process. As illustrated in FIG. 1B, bubble fragments 43a, 43b and 43c fly off from the edge portion and attach to the unexposed portion of the photosensitive resist layer 43. Development of the photosensitive resist layer 43 is then performed. As a result, abnormal resist patterns 43ra, 43rb and 43rc as illustrated in FIG. 1C are formed. Thereafter, etching of the underlying layer 41 is performed using the abnormal resist patterns 43ra, 43rb and 43rc as an etch mask, leading to abnormal processed patterns 41pa, 41pb and 41pc as illustrated in FIG. 1D.

In order to avoid the bubble phenomenon, wafer edge exposure techniques are disclosed in, for example, Japanese Patent Application Publication No. 1993(H05)-205991, Japanese Examined Patent Publication No. 1995(H07)-50676 and Japanese Examined Patent Publication No. 1995(H07)-50677. In the wafer edge exposure techniques disclosed in these publications, a photosensitive resin material on the peripheral edge of a wafer is exposed to light more than once using multiple exposure steps. This enables a low exposure energy dose per unit time for each exposure step thereby to avoid a photochemical reaction.

The use of the multiple exposure steps, however, is difficult to completely avoid the bubble phenomenon, thus possibly causing defects in a photoresist pattern and lower manufacturing yield. Therefore, more effective techniques to avoid the bubble phenomenon have been required.

In view of the foregoing, it is an object of the present invention to provide a system and method for processing a substrate to effectively avoid the bubble phenomenon that is caused by light exposure of a photosensitive resin material.

### SUMMARY OF THE INVENTION

According to an aspect of the present invention, there is provided a system for processing a substrate. The system includes: a cleaning equipment for cleaning a surface of a substrate; a resist coating equipment for coating the surface of the substrate with a photosensitive material to form a resist layer; an edge exposure equipment for exposing to light an edge portion of the resist layer, the edge portion being formed on a peripheral edge of the substrate; a substrate transport mechanism for transporting the substrate from the resist coating equipment into the edge exposure equipment; and a system controller for operatively controlling the cleaning equipment, the resist coating equipment and the edge exposure equipment, individually. The system controller includes a waiting time monitor for monitoring a waiting time that is a time interval between the formation of the resist layer and start of the exposure of the edge portion of the resist layer; and a process controller for causing the substrate transport mechanism to transport the substrate into the cleaning equipment when the monitored waiting time exceeds a prescribed limit, thereby to remove the resist layer from the substrate, and thereafter causing the substrate transport mechanism to transport the substrate from the cleaning equipment into the resist coating equipment.

According to another aspect of the present invention, there is provided a method of processing a substrate in a system which comprises a cleaning equipment for cleaning a surface of a substrate, a resist coating equipment for coating the surface of the substrate with a photosensitive material to form a resist layer, an edge exposure equipment for exposing to light an edge portion of the resist layer formed on a peripheral edge of the substrate, and a substrate transport mechanism for transporting the substrate from the resist coating equipment into the edge exposure equipment. This method includes: monitoring a waiting time that is a time interval between the formation of the resist layer and start of the exposure of the edge portion of the resist layer; controlling the substrate transport mechanism to transport the substrate into the cleaning equipment when the monitored waiting time exceeds a prescribed limit, thereby to remove the resist layer from the substrate; and thereafter controlling the substrate transport mechanism to transport the substrate from the cleaning equipment into the resist coating equipment.

According to the aspects of the present invention, the bubble phenomenon can be effectively avoid thereby to reduce defects in the resist pattern.

### BRIEF DESCRIPTION OF THE DRAWINGS

In the attached drawings:

FIGS. 1A to 1D are cross-sectional views illustrating exemplary pattern defects caused by bubble phenomenon in a conventional wafer edge exposure process;

FIG. 2 schematically illustrates a functional block diagram of a substrate processing system that is an embodiment according to the present invention;

FIG. 3 is a schematic of an exemplary edge exposure equipment of the embodiment;

FIG. 4 is an exemplary operation flow chart depicting a method of monitoring a waiting time until an exposure of an edge portion of a resist layer is started;

FIGS. 5A to 5C are schematic views for explaining a sequence of a wafer edge exposure;

FIG. 6 illustrates a table in which experimental parameters are listed;

FIG. 7 illustrates a table in which another experimental parameters are listed;

FIG. 8 illustrates a table in which still another experimental parameters are listed; and

FIG. 9 illustrates a table in which yet another experimental parameters are listed.

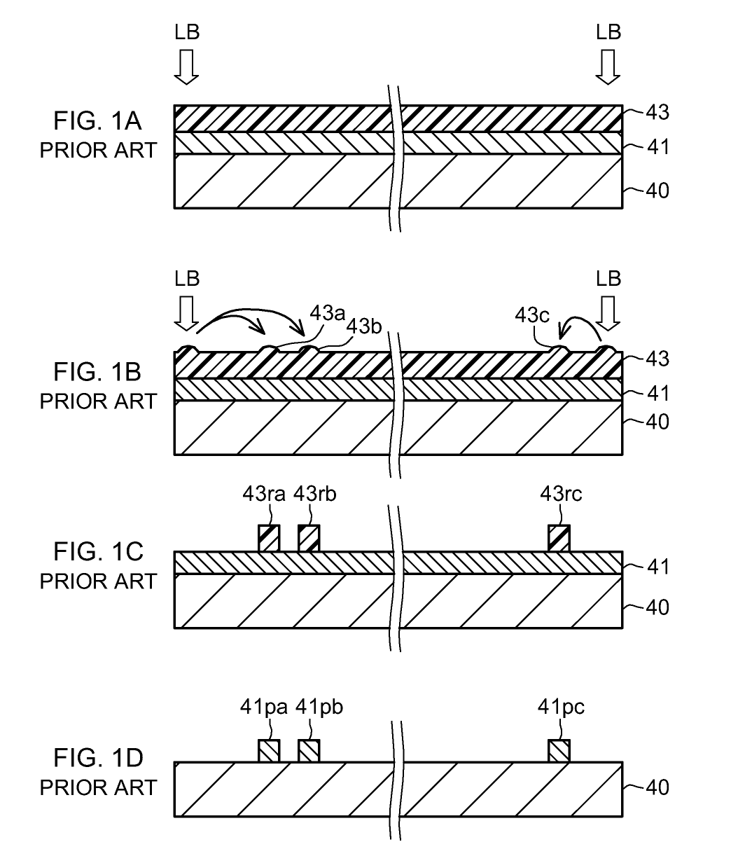

### DETAILED DESCRIPTION OF THE INVENTION

Embodiments of the invention will now be described with reference to the attached drawings, in which like elements are indicated by like reference characters.

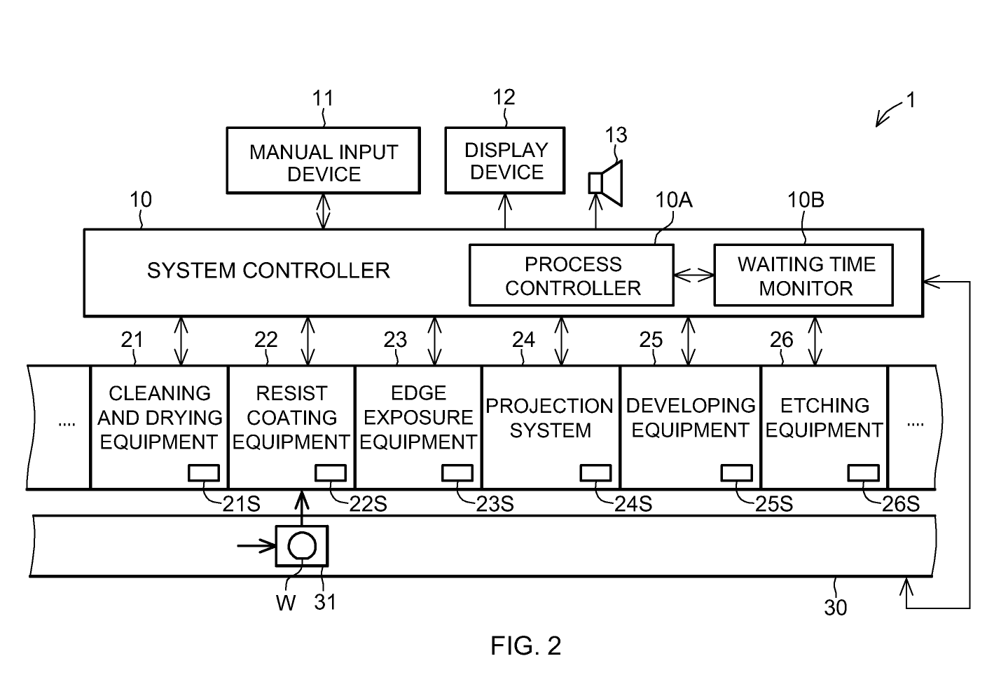

FIG. 2 schematically illustrates a functional block diagram of a substrate processing system 1 that is an embodiment according to the present invention. As illustrated in FIG. 2, the substrate processing system 1 includes a plurality of equipments for fabricating semiconductor integrated circuits on and/or in a wafer (a substrate) W. Specifically, the substrate processing system 1 includes a cleaning and drying equipment (a washing equipment) 21, a resist coating equipment 22, an edge exposure equipment 23, a projection system or stepper 24, and a developing equipment 25, and an etching equipment 26. It is to be noted that FIG. 2 illustrates a part of the substrate processing system 1 which includes other equipments (not shown) capable of operating in association with the equipments 21 to 26 illustrated in FIG. 2.

The substrate processing system 1 further includes a substrate transport mechanism or substrate carrier assembly 30 that transports a substrate carrier 31 capable of holding and carrying a plurality of wafers (substrates) per batch. The substrate transport mechanism 30 has a function of transporting the substrate carrier 31 into/from any one of the equipments 21 to 26 in accordance with commands provided by a system controller 10. Thus, the substrate transport mechanism 30 can transport the substrate carrier 31 from one of the equipments 21 to 26 into another one of the equipments 21 to 26 in accordance with commands provided by the system controller 10.

The substrate processing system 1 includes the system controller 10 capable of individually controlling the operations of the equipments 21 to 26 and the substrate transport mechanism 30; a manual input device or operation panel 11; a display device 12 such as a monitor; and an audio output device 13 such as a speaker. An operator can operate the manual input device 11 to enter information indicating process conditions. The system controller 10 is capable of performing processing in response to the entered information. The display device 12 has a display unit such as an LCD (Liquid Crystal Display) module that displays the image data provided by the system controller 10.

The system controller 10 further includes a process controller 10A capable of controlling a series of processes to be performed by the equipments 21 to 26 in a production line; and a waiting time monitor 10B that monitors a waiting or queueing time with respect to each wafer W that is ready for a next processing step. This system controller 10 can be comprised of a microprocessor, a ROM (Read Only Memory), a RAM (Random Access Memory), and an input/output interface. All or part of the functions of the system controller 10 can be implemented by hardware and/or the software program or set of codes that is executed by the microprocessor such as a CPU (Central Processing Unit) or MPU (Microprocessor Unit). When all or part of the functions of the system controller 10 is implemented by the software program, the microprocessor fetches the software program from a recording medium (not shown) such as a nonvolatile memory, and executes the software program to perform the functions.

The resist coating equipment 22 can coat the main surface of a loaded wafer W with a positive-type photosensitive resin material with uniform thickness to form a resist layer on the main surface. An underlying layer is formed on the wafer W by a deposition system (not shown) before the loading of the wafer W into the resist coating equipment 22. The resist coating equipment 22 deposits the resist layer on the underlying layer. The resist coating equipment 22 includes a position detection sensor 22S that detects the current position of the wafer W by electromagnetic, optical or mechanical sensing, thereby detecting whether or not the coating process for the wafer W is completed. The detection result obtained by the position detection sensor 22S is fed to the system controller 10.

After the formation of the resist layer, the substrate carrier 31 holding the wafer W is transported from the resist coating equipment 22. Next, in the normal process where the waiting time for the next wafer edge exposure process is less than or equal to a prescribed limit, the wafer W is transported into the edge exposure equipment 23.

On the other hand, in the case where the waiting time exceeds the prescribed limit, the wafer W is transported and loaded into the cleaning and drying equipment 21 instead of the edge exposure equipment 23. In this case, the cleaning and drying equipment 21 removes the resist layer of the loaded wafer W by cleaning. Next, the wafer W is transported from the cleaning and drying equipment 21 and loaded into the resist coating equipment 22. The resist coating equipment 22 coats the main surface of the loaded wafer W with a photosensitive resin material to form a resist layer on the main surface again. Since the cleaning and drying equipment 21 includes a position detection sensor 21S that detects the current position of the wafer W by electromagnetic, optical or mechanical sensing, thereby detecting whether or not the cleaning process for the wafer W is completed. The detection result obtained by the position detection sensor 21S is fed to the system controller 10.

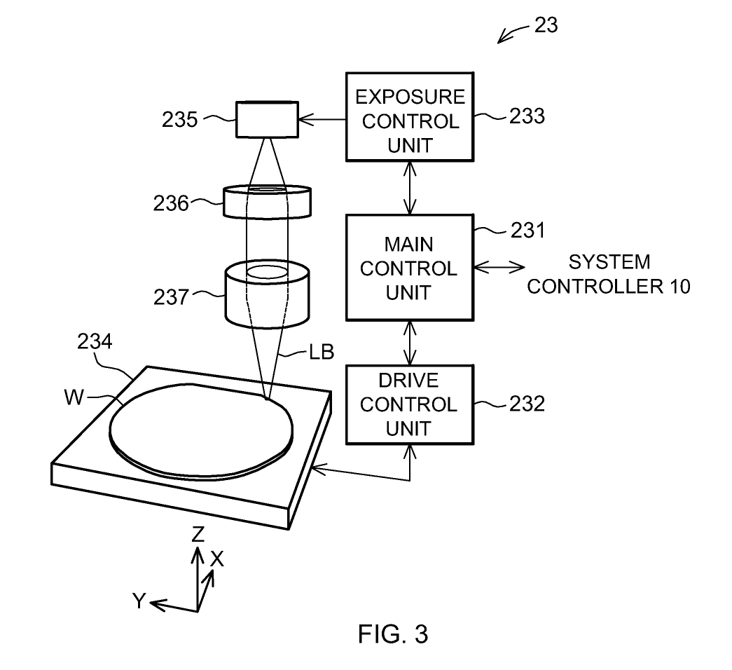

The edge exposure equipment 23 exposes only an unnecessary portion of the resist layer formed entirely on the main surface of the wafer W, where the unnecessary portion is formed on the peripheral edge of the wafer W. FIG. 3 is an exemplary schematic of the edge exposure equipment 23. As illustrated in FIG. 3, the edge exposure equipment 23 includes: a stage 234 on which a wafer W is mounted; a light source 235; a condenser lens 236; and an objective lens 237. The stage 234 moves the wafer W along any one of the X-axis direction, Y-axis direction and Z-axis direction to position the wafer W with respect to a light beam LB, in accordance with commands provided by a drive control unit 232. The upper surface of the stage 234 is capable of holding the wafer W in place by chucking. The light source 235 can be a discharge lamp that provides an intensity at i-line (about 365 nm wavelength), no limitation thereto intended.

The edge exposure equipment 23 further includes: an exposure control unit 233 capable of operatively controlling the light source 235 to adjust an intensity of illumination; the drive control unit 232 capable of operatively controlling the stage 234; and a main control unit 231 capable of controlling the operations of the drive control unit 232 and the exposure control unit 233 in response to commands provided by the system controller 10. A wafer loading and unloading mechanism (not shown) such as a robotic arm is installed in the edge exposure equipment 23.

A light beam LB emitted by the light source 235 passes through the condenser lens 236, and is collected into the wafer W by the objective lens 237 to illuminate the peripheral edge of the wafer W. At this time, the stage 234 moves the wafer W such that the illuminating light beam LB scans the peripheral edge in the circumferential direction of the wafer W. The illuminating light beam LB can scan the peripheral edge in the clockwise or counter-clockwise direction. The edge exposure equipment 23 exposes the peripheral edge to the light beam LB at a relatively low intensity of illumination more than once using multiple exposure steps, thereby avoiding a photochemical reaction in the exposed portion of the resist layer.

After the exposure of the peripheral edge, the wafer W is held by the substrate carrier 31 and unloaded from the edge exposure equipment 23. The unloaded wafer W is transported and loaded into the projection system 24 after a waiting time. The edge exposure equipment 23 includes a position detection sensor 23S that detects the current position of the wafer W by electromagnetic, optical or mechanical sensing, thereby detecting whether or not the wafer edge exposure process for the wafer W is completed. The detection result obtained by the position detection sensor 23S is fed to the system controller 10.

The projection system 24 performs a projection process for photolithography. Namely, the projection system 24 exposes the resist layer on the wafer W to a pattern of light that passes a reticle (not shown), thus transferring master patterns of the reticle onto the resist layer. The exposed portion of the resist layer on the wafer W undergoes a photochemical reaction to make the exposed portion dissolvable in an alkaline developing solution. After the projection process, the wafer W is held by the substrate carrier 31 and unloaded from the projection system 24. The unloaded wafer W is transported and loaded into the developing equipment 25 after a waiting time. The projection system 24 includes a position detection sensor 24S that detects the current position of the wafer W by electromagnetic, optical or mechanical sensing, thereby detecting whether or not the projection process for the wafer W is completed. The detection result obtained by the position detection sensor 24S is fed to the system controller 10.

The developing equipment 25 performs a developing process in which the exposed portion of the resist layer is removed by using a developing solution. As a result, a resist pattern is formed on the wafer W. After the developing process, the wafer W is held by the substrate carrier 31 and unloaded from the developing equipment 25. The unloaded wafer W is transported and loaded into the etching equipment 26 after a waiting time. The developing equipment 25 includes a position detection sensor 25S that detects the current position of the wafer W by electromagnetic, optical or mechanical sensing, thereby detecting whether or not the developing process for the wafer W is completed. The detection result obtained by the position detection sensor 25S is fed to the system controller 10.

The etching equipment 26 selectively etches the underlying layer beneath the resist pattern by wet or dry etching using the resist pattern as an etching mask. After the etching, the wafer W is held by the substrate carrier 31 and unloaded from the etching equipment 26. The etching equipment 26 includes a position detection sensor 26S that detects the current position of the wafer W by electromagnetic, optical or mechanical sensing, thereby detecting whether or not the etching process for the wafer W is completed. The detection result obtained by the position detection sensor 26S is fed to the system controller 10.

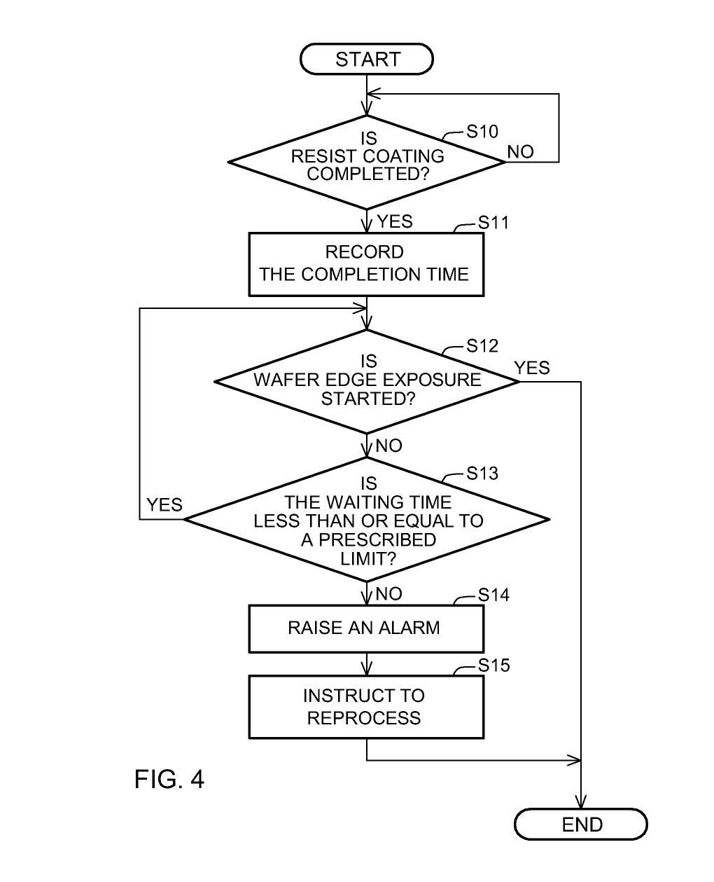

The waiting time monitor 10B monitors the waiting times for each wafer W based on the detection results provided by the position detection sensors 21S to 26S. FIG. 4 is an exemplary operation flow chart depicting a method of monitoring a waiting time until the wafer edge exposure process is started. The method of monitoring the waiting time will now be described with reference to FIG. 4.

The waiting time monitor 10B detects the start of the resist coating process performed by the resist coating equipment 22 on the basis of the detection result provided by the position detection sensor 22S. The waiting time monitor 10B then starts a waiting time monitoring process as illustrated in FIG. 4. The waiting time monitor 10B is ready until the resist coating process is completed (“NO” in step S10). When detecting the completion of the resist coating process (“YES” in step S10), the waiting time monitor 10B records the completion time (step S11).

Next, based on the detection result provided by the position detection sensor 23S, the waiting time monitor 10B checks whether or not the next wafer edge exposure process has been started by the edge exposure equipment 23 (step S12). When the next wafer edge exposure process has not been started (“NO” in step S12), the waiting time monitor 10B further checks whether or not the waiting time is less than or equal to the prescribed limit (step S13). When the waiting time is less than or equal to the prescribed limit (“YES” in step S13), the procedure returns back to step S12.

When the wafer edge exposure process is started before the waiting time exceeds the prescribed limit (“YES” in step S13 and “YES” in step S12), the waiting time monitor 10B ends the waiting time monitoring process for the wafer W.

On the other hand, when the waiting time exceeds the prescribed limit (“NO” in step S13), the waiting time monitor 10B raises an alarm to an operator by causing the display device 12 to display a visual signal and/or by causing the audio output device 13 to generate an audio signal (step S14). Next, the waiting time monitor 10B instructs to the process controller 10A to reprocess for the wafer W (step S15), and then ends the waiting time monitoring process. As a result, the wafer W is transported and loaded into the cleaning and drying equipment 21 in which the resist layer is removed from the wafer W. Next, the wafer W is transported from the cleaning and drying equipment 21, and loaded into the resist coating equipment 22 in which a resist layer is formed on the wafer again. After the formation of the resist layer, the wafer W is unloaded from the resist coating equipment 22. Thereafter, in accordance with the waiting time monitoring process described above, the wafer W is loaded into the edge exposure equipment 23 when the waiting time is less than or equal to the prescribed limit. On the other hand, the wafer W is loaded into the cleaning and drying equipment 21 when the waiting time exceeds the prescribed limit.

As described above, the resist layer is removed from the wafer W when the waiting time exceeds the prescribed limit. The reason for doing so is that variation in the waiting time among the wafers W possibly induces bubble phenomenon in the wafer edge exposure process. The waiting time is a time interval between the formation of the resist layer and the start of the wafer edge exposure. The larger the waiting time, the more likely the bubble phenomenon occurs in the wafer edge exposure process. In this regard, the experiments performed by the inventor will be described.

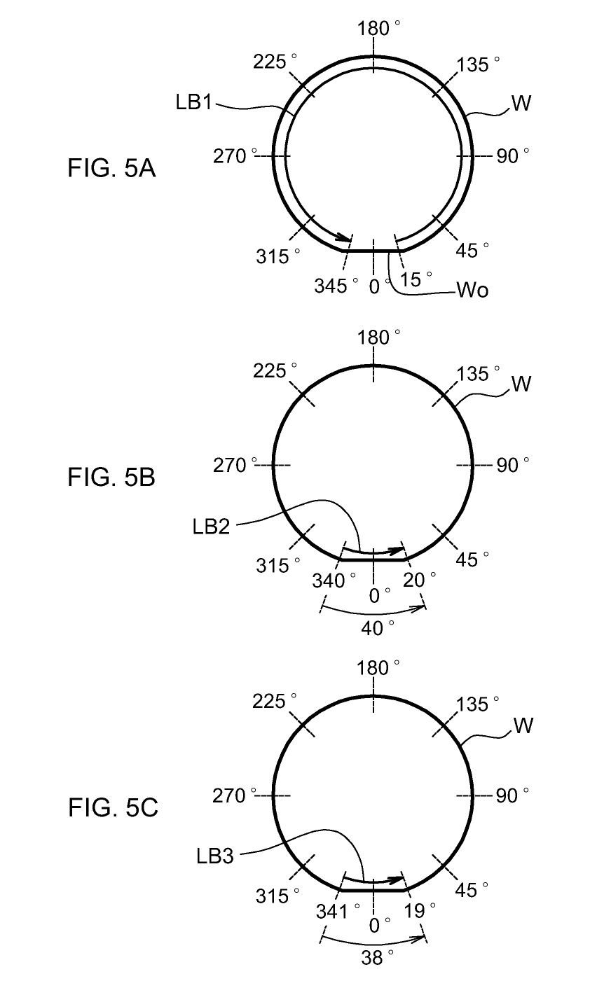

FIGS. 5A to 5C are schematic views for explaining a sequence of a wafer edge exposure that is used for the experiment. FIGS. 5A to 5C illustrate the top surface (i.e., the main surface) of a silicon wafer W that has an orientation flat Wo. The angular position of the center of the silicon wafer W corresponds to an angle of zero degrees. The top surface of the silicon wafer W was entirely coated with a resist layer (thickness: about 2.5 micrometers) that is composed of the photosensitive resist material “THMR-iP 2900” manufactured by TOKYO OHKA KOGYO. The periphery of the resist layer formed on the peripheral edge of the wafer W was exposed to a light beam.

In the step illustrated in FIG. 5A, the edge exposure equipment 23 controls the trajectory of a light beam LB1 (i-line) for edge exposure on the resist layer so that the light beam LB1 scans the resist layer starting from a first position at a starting angle of 15 degrees up to a second position at an ending angle of 345 degrees. The first position is in the vicinity of one end of the orientation flat Wo, and the second position is in the vicinity of the other end of the orientation flat Wo. The position of the light beam LB1 on the resist layer is moved in the counter-clockwise direction on a circular arc region along the peripheral edge of the silicon wafer W. The moving position of the light beam LB1 on the resist layer is set to be at a distance about 3.0 mm inward from an outer edge of the silicon wafer W.

In the next step illustrated in FIG. 5B, the edge exposure equipment 23 controls the trajectory of a light beam LB2 (i-line) for edge exposure on the resist layer so that the light beam LB2 scans the resist layer starting from a third position at a starting angle of 340 degrees up to a fourth position at an ending angle of 20 degrees. The position of the light beam LB2 on the resist layer is moved in the counter-clockwise direction on a circular arc region. The moving position of the light beam LB2 on the resist layer is set to be at a distance about 3.3 mm inward from an outer edge of the silicon wafer W.

In the next step illustrated in FIG. 5C, the edge exposure equipment 23 controls the trajectory of a light beam LB3 (i-line) for edge exposure on the resist layer so that the light beam LB3 scans the resist layer starting from a fifth position at a starting angle of 341 degrees up to a sixth position at an ending angle of 19 degrees. The position of the light beam LB3 on the resist layer is moved in the counter-clockwise direction on a circular arc region. The moving position of the light beam LB3 on the resist layer is set to be at a distance about 3.5 mm inward from an outer edge of the silicon wafer W.

The sequence of the wafer edge exposure shown in FIGS. 5A to 5C was used as a basic sequence per one rotation. The basic sequences with different exposure energy doses for one to four rotations were performed. In this experiment, an exposure filter (i.e., a wavelength-selective filter) was not used in the edge exposure equipment 23, and an integrator control for controlling the exposure energy doses was used.

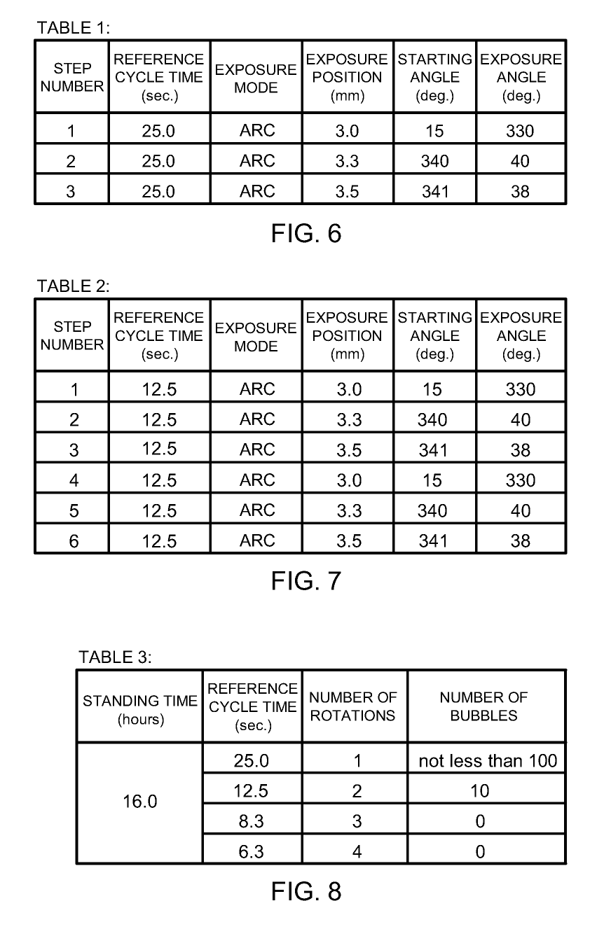

In the case of a sequence for one rotation (experiment 1), an exposure energy dose (an integral amount) was set to about 25000 mJ/cm², and a reference cycle time (i.e., an exposure time) was set to about 25.0 seconds. Experimental parameters used for this sequence are listed in TABLE 1 illustrated in FIG. 6.

In the case of another sequence for two rotations (experiment 2), an exposure energy dose (an integral amount) per one rotation was set to about 12500 mJ/cm² that is one-half of the exposure energy dose set in the case of experiment 1, and a reference cycle time per one rotation was set to about 12.5 seconds. Experimental parameters used for this sequence are listed in TABLE 2 illustrated in FIG. 7.

In the case of still another sequence for three rotations (experiment 3), an exposure energy dose (an integral amount) per one rotation was set to about 8333 mJ/cm² that is one-third of the exposure energy dose set in the case of experiment 1, and a reference cycle time per one rotation was set to about 8.33 seconds. In the case of yet another sequence for four rotations (experiment 3), an exposure energy dose (an integral amount) per one rotation was set to about 6250 mJ/cm² that is one-fourth of the exposure energy dose set in the case of experiment 1, and a reference cycle time per one rotation was set to about 6.25 seconds.

Bubbles generated in the resist layer due to each of the above sequences for one to fourth rotations was observed and counted under an optical microscope. The results are listed in TABLE 3 illustrated in FIG. 8.

In TABLE 3, “STANDING TIME” means the period of time from the time point when the formation of the resist layer on the silicon wafer W is completed, up to the current time point. The standing time was set to 16.0 hours. As seen in TABLE 3, the shorter the reference cycle time to lower the exposure energy dose per one rotation, the more the bubble generation is suppressed.

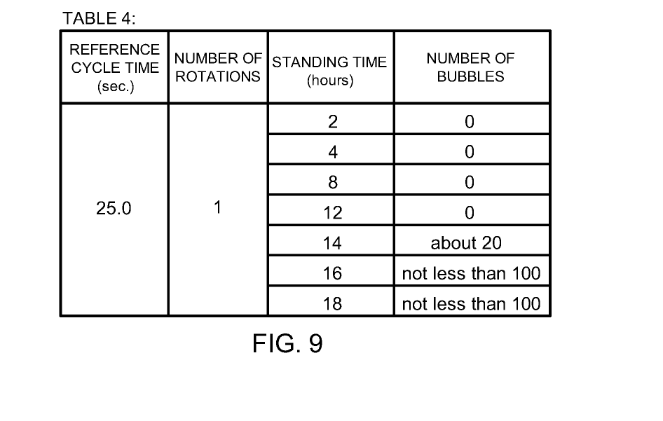

Further, experiment 1 for one rotation was performed in a different setting of the standing time. Then, bubbles generated in the resist layer due to the edge exposure for one rotation was observed and counted under an optical microscope. The results are listed in TABLE 4 illustrated in FIG. 9.

As seen in TABLE 4, it is understood that the shorter the standing time, the more the bubble generation is suppressed even in the edge exposure for one rotation. Particularly, the number of bubbles is zero when the standing time is not over 12 hours. Thus, the defects in the photoresist pattern can be effectively reduced when the prescribed limit for the waiting time is set to 12 hours.

As described above, when the monitored waiting time exceeds the prescribed limit after the formation of the resist layer, the substrate processing system 1 of the present embodiment performs reprocessing in which the resist layer is removed from the wafer W. This enables avoiding the occurrence of the bubble phenomenon that is caused by the wafer edge exposure process. Therefore, the defects in the photoresist pattern can be effectively reduced.

The invention is not limited to the embodiments described above and shown in the drawings. Those skilled in the art will recognize that further variations are possible within the scope of the invention, which is defined in the appended claims.

What is claimed is:

1. A system for processing a substrate, comprising:
a cleaning equipment for cleaning a surface of a substrate;
a resist coating equipment for coating the surface of the substrate with a photosensitive material to form a resist layer;
an edge exposure equipment for exposing to light an edge portion of the resist layer, the edge portion being formed on a peripheral edge of the substrate;
a substrate transport mechanism for transporting the substrate from the resist coating equipment into the edge exposure equipment; and
a system controller for operatively controlling the cleaning equipment, the resist coating equipment and the edge exposure equipment, individually, the system controller including:
a waiting time monitor for monitoring a waiting time that is a time interval between the formation of the resist layer and start of the exposure of the edge portion of the resist layer; and
a process controller for causing the substrate transport mechanism to transport the substrate into the cleaning equipment when the monitored waiting time exceeds a prescribed limit, thereby to remove the resist layer from the substrate, and thereafter causing the substrate transport mechanism to transport the substrate from the cleaning equipment into the resist coating equipment.

2. The system according to claim 1, wherein the edge exposure equipment exposes to light the edge portion of the resist layer more than once.

3. The system according to claim 1, further comprising a notification device for generating a visual signal or an audio signal to raise an alarm when the monitored waiting time exceeds the prescribed limit.

4. The system according to claim 1, wherein the substrate is a semiconductor wafer.

5. A method of processing a substrate in a system which comprises a cleaning equipment for cleaning a surface of a substrate, a resist coating equipment for coating the surface of the substrate with a photosensitive material to form a resist layer, an edge exposure equipment for exposing to light an edge portion of the resist layer formed on a peripheral edge of the substrate, and a substrate transport mechanism for transporting the substrate from the resist coating equipment into the edge exposure equipment, said method comprising:
monitoring a waiting time that is a time interval between the formation of the resist layer and start of the exposure of the edge portion of the resist layer;
controlling the substrate transport mechanism to transport the substrate into the cleaning equipment when the monitored waiting time exceeds a prescribed limit, thereby to remove the resist layer from the substrate; and
thereafter controlling the substrate transport mechanism to transport the substrate from the cleaning equipment into the resist coating equipment.

6. The method according to claim 5, further comprising controlling the edge exposure equipment to expose to light the edge portion of the resist layer more than once.

7. The method according to claim 5, further comprising generating a visual signal or an audio signal to raise an alarm when the monitored waiting time exceeds the prescribed limit.
